(19) United States
(12) Patent Application Publication
(10) Pub. No.: US 2013/0149515 A1
(43) Pub. Date: Jun. 13, 2013

(54) MANUFACTURING METHOD OF MULTILAYER POLYIMIDE FLEXIBLE METAL-CLAD LAMINATE

(71) Applicant: SK INNOVATION CO., LTD., Seoul (KR)

(72) Inventors: Byoung Wook JO, Daejeon (KR); Young Do KIM, Daejeon (KR); Seung Jeong KOOK, Daejeon (KR)

(73) Assignee: SK INNOVATION CO., LTD., Seoul (KR)

(21) Appl. No.: 13/706,479

(22) Filed: Dec. 6, 2012

(30) Foreign Application Priority Data
Dec. 7, 2011 (KR) 10-2011-0130001

(51) Int. Cl. H05K 1/03

(52) U.S. Cl. CPC H05K 1/0393
USPC 428/216; 428/212; 427/385.5; 427/388.2; 427/358

(57) ABSTRACT

Provided is a multilayer polyimide flexible metal-clad laminate where multiple layers of polyimide are structured on one surface or two surfaces of a metal foil, the multilayer polyimide flexible metal-clad laminate including: multiple layers of polyimide having different coefficients of linear thermal expansion; and gradient layers each formed between polyimide layers of the multiple layers of polyimide, the gradient layer having a gradual change in coefficient of linear thermal expansion between the polyimide layers, and a manufacturing method thereof, so that there can be provided a flexible metal-clad laminate for a printed circuit board capable of solving a delamination problem between the polyimide layers and having excellent dimensional stability.

### CROSS-REFERENCE TO RELATED APPLICATIONS

This application claims priority under 35 U.S.C. §119 to Korean Patent Application No. 10-2011-013001, filed on Dec. 7, 2011, in the Korean Intellectual Property Office, the disclosure of which is incorporated herein by reference in its entirety.

### TECHNICAL FIELD

The following disclosure relates to a multilayer polyimide flexible metal-clad laminate and a manufacturing method thereof, and more particularly, to a multilayer polyimide flexible metal-clad laminate where two or more polyimide layers are structured on one surface or two surfaces of the metal foil, capable of having excellent adhesive strength between a metal foil and a polyimide layer and suppressing a delamination occurring in an interface between the polyimide layers having different coefficients of linear thermal expansion.

### BACKGROUND

As electronic devices become smaller, multi-functional, and thinner, printed circuit boards used in the electronic devices are also needed to have high degree of integration. In order to meet this need, a method for making a printed circuit board be multilayered may be used. In addition, a flexible printed circuit board having flexibility may be used so as to be installed in a thinner and narrower space, and a circuit having a narrower line width may be used to obtain as many circuits as possible in the same space to achieve a high performance.

In the method of manufacturing a multilayered printed circuit board, soldering may cause environmental problems. Therefore, for the multilayered printed circuit board, an adhesive having high adhesion, high heat resistance, and low moisture absorption is needed. However, a metal-clad laminate of the related art, where a polyimide film and a metal foil are attached to each other by using an acryl-based or epoxy-based adhesive, is not appropriate in a printed circuit board requiring multiple layers, flexibility, high adhesion, and high heat resistance. Therefore, a 2-Layer Copper Clad Laminate (2CCL) type flexible metal-clad laminate, where a polyimide layer and a metal foil are directly attached to each other without using an adhesive, has been developed. This metal-clad laminate is a flexible printed circuit board material having thermal stability, durability, and electrical characteristics, higher than those of a 3-Layer Copper Clad Laminate (3CCL) where a metal layer and a polyimide layer are attached to each other by using the existing adhesive.

The 2-Layer Copper Clad Laminate (2CCL) type flexible metal-clad laminate may be largely classified into a single-sided metal-clad laminate composed of a metal foil and a polyimide layer and a double-sided metal-clad laminate where a polyimide layer is present between two layers of metal foil. Here, in most cases, the polyimide layer may be generally composed of multi-layers of polyimide including two or more polyimide layers having different coefficients of linear thermal expansion in order to meet characteristics such as adhesion with metal, dimensional stability, etc. Korean Patent Laid-Open Publication No. 10-2009-0066399 (Patent Document 1) discloses a polyimide metal foil laminate having different coefficient of thermal expansion.

Generally, multiple layers of polyimide are formed by coating polyamic acid varnish, which is a precursor of polyimide, on a metal foil such that a desired number of layers are coated and dried, repeatedly. In particular, in order to enhance the adhesion with the metal foil, it is general to firstly coat and dry a polyimide precursor layer having a high coefficient of linear thermal expansion on a metal foil, and then coat and dry a polyimide precursor layer having a low coefficient of linear thermal expansion thereon for the purpose of decreasing the dimensional change. Here, since the firstly dried polyimide precursor layer has been in a solidified state, mixing between layers hardly occurs while the subsequently coated polyimide precursor layer is coated and dried, and thus the coefficient of linear thermal expansion in a thickness direction is rapidly varied based on the interface between the polyimide layers. After that, an imidization process (hereinafter, used in the same meaning as the term ‘curing process’) is conducted at a high temperature of 300° C. or higher. Here, interfacial stress may occur at the interface between the polyimide layers having different coefficients of linear thermal expansion, which may cause defects, such as bubble formation and more severely delamination. This delamination problem may be suppressed by lowering the rate of temperature increase to the maximum temperature or increasing the curing time. However, in the case of using a roll to roll type curing machine, the curing time therefor is shorter in comparison with a batch type curing machine and the retention time in the curing machine is directly associated with productivity, and thus other solutions are needed.

### RELATED ART DOCUMENT

### Patent Document

(Patent Document 1) Korean Patent Laid-Open Publication No. 10-2009-0066399

### SUMMARY

An embodiment of the present invention is directed to providing a multilayer polyimide flexible metal-clad laminate where two or more polyimide layers are structured on one surface or both surfaces of a metal foil, capable of suppressing a delamination problem occurring at the time of curing in the procedure where polyimide having superior adhesion with the metal foil and excellent dimensional stability is structured on the metal foil, and a manufacturing method thereof.

In one general aspect, there is provided a multilayer polyimide flexible metal-clad laminate where multiple layers of polyimide are laminated on one surface or two surfaces of a metal foil, the multilayer polyimide flexible metal-clad laminate including: multiple layers of polyimide having different coefficients of linear thermal expansion; and gradient layers each formed between polyimide layers of the multiple layers of polyimide, the gradient layer having a gradient due to a difference in coefficient of linear thermal expansion between the polyimide layers.

In another general aspect, there is provided a manufacturing method of a multilayer polyimide flexible metal-clad laminate on one surface or two surfaces of a metal foil, the method including: coating two or more polyimide precursor layers continuously without drying, by drying and curing at a time, to thereby form multiple layers of polyimide and gradient layers each between polyimide layers of the multiple layers of polyimide, the gradient layer having a gradual change in coefficient of linear thermal expansion between the polyimide layers.

### BRIEF DESCRIPTION OF THE DRAWINGS

FIG. 1 is a cross-sectional view of a laminate formed by continuously multi-coat three different polyimide precursor layers, followed by drying and imidization; and

FIG. 2 is a schematic diagram showing a structure where the coefficient of linear thermal expansion is not rapidly changed but has a gradient between polyimide layers having different coefficients of linear thermal expansion, due to a mixing effect in a gradient layer. Here, a portion indicated by the term ‘mixing’ represents a portion where different polyimide layers are mixed.

### DETAILED DESCRIPTION OF MAIN ELEMENTS

10: first polyimide layer having high coefficient of thermal expansion
20: second polyimide layer having low coefficient of thermal expansion
30: third polyimide layer having high coefficient of thermal expansion
40: gradient layer (mixing layer) of first polyimide layer and second polyimide layer
50: gradient layer (mixing layer) of second polyimide layer and third polyimide layer
60: metal foil

### DETAILED DESCRIPTION OF EMBODIMENTS

Hereinafter, the present invention will be described in detail with reference to the accompanying drawings.

The present invention provides a multilayer polyimide flexible metal-clad laminate where multiple layers of polyimide are structured on one surface or two surfaces of a metal foil, which is characterized by including: multiple layers of polyimide having different coefficients of linear thermal expansion; and gradient layers each formed between polyimide layers of the multiple layers of polyimide, the gradient layer having a gradual change in coefficient of linear thermal expansion between the polyimide layers.

More specifically, in the multilayer polyimide flexible metal-clad laminate, the multiple layers of polyimide may include an n-th (n≧1) polyimide layer and an n+1-th (n≧1) polyimide layer; and the gradient layers may include a gradient layer of the n-th polyimide layer and the n+1-th polyimide layer, the gradient layer having a gradual change in coefficient of linear thermal expansion between the n-th polyimide layer and the n+1-th polyimide layer.

Here, the polyimide layers each may have a coefficient of linear thermal expansion of 10˜100 ppm/K.

In addition, the difference in coefficient of linear thermal expansion between the polyimide layers may be 10˜90 ppm/K.

The multilayer polyimide flexible metal-clad laminate of the present invention is characterized by including gradient layers each formed between the polyimide layers of the multiple layers of polyimide, the gradient layer having a gradient due to the difference in coefficient of linear thermal expansion between the polyimide layers.

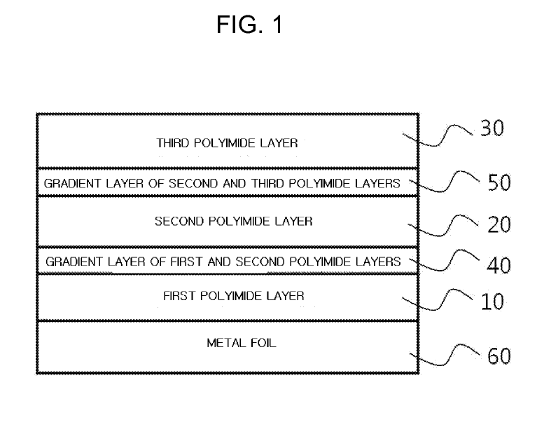

In other words, in the multilayer polyimide flexible metal-clad laminate of the present invention, since different polyimide precursor layers are continuously coated, drying is simultaneously carried out while the respective layers are not in a solidified state. In this case, as the solvent is evaporated, a polyimide precursor that is positioned at a relatively lower layer moves up together with the solvent, and then mixed with a polyimide precursor that is positioned at a relatively higher layer, with the result that an interface between the two layers disappears and a few micrometer-thick mixing layer is formed. Due to formation of this mixing layer, the change in coefficient of linear thermal expansion in a thickness direction is gradual in the interface of the layers. This is defined as “gradient” herein. FIG. 1 is a schematic diagram of this gradient layer. Here, a gradient layer of the first and second polyimide layers 40 is formed by allowing a first polyimide layer 10 to penetrate into an upper layer, a second polyimide layer 20, and a gradient layer of the second and third polyimide layers 50 is formed by allowing the second polyimide layer 20 to penetrate into an upper layer, a third polyimide layer 30.

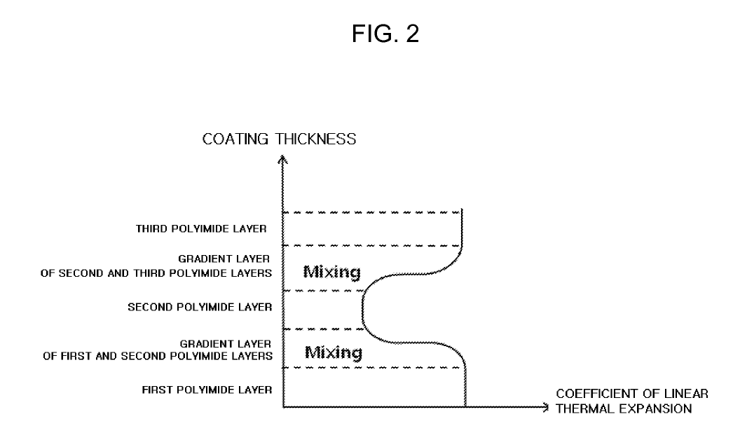

Resultantly, while the polyimide precursor layers are cured, these gradient layers (mixing layers) serve to suppress generation of interfacial stress due to a change in the extent of thermal expansion between the respective layers, resulting in remarkably reducing a bubble formation or delamination problem. FIG. 2 is a schematic diagram of the gradient layer of which a gradient is formed between the layers of the multiple layers of polyimide due to the difference in coefficient of linear thermal expansion.

The present invention is characterized in that the polyimide layers each have a thickness of 1˜30 μm.

In the present invention, the metal foil is preferably selected from copper, aluminum, iron, silver, palladium, nickel, chrome, molybdenum, tungsten, and an alloy thereof. Generally, copper may be widely used, but the metal foil of the present invention is not limited thereto.

Next, a polyimide precursor solution used to make the polyimide precursor layer, which is a constituent of the present invention, will be described in detail.

The polyimide precursor solution is formed into the polyimide precursor layer through coating and drying, and the polyimide precursor layer is subjected to poly-imidization through curing process, thereby forming the polyimide layer.

The polyimide precursor solution may be prepared in a varnish type where dianhydride and diamine are mixed at a mole ratio of 1:0.9 to 1:1.1 in an appropriate organic solvent. The thus obtained varnish is coated on a metal plate once or more and then dried, to thereby form the polyimide precursor layer. In the present invention, when the polyimide precursor solution is prepared, a polyimide based resin having a desired coefficient of thermal expansion may be obtained by controlling the mixing ratio between dianhydride and diamine or the mixing ratio between dianhydrides or between diamines, or by adjusting the kinds of dianhydride and diamine selected.

As the dianhydride suitable in the present invention, at least one selected from the group consisting of pyromellitic dianhydride (PMDA), 3,3′,4,4′-biphenyltetracarboxylic dianhydride (BPDA), 3,3′,4,4′-benzophenonetetracarboxylic dianhydride (BTDA), 4,4′-oxidiphthalic anhydride (ODPA), 4,4′-diaminodiphenyl ether (ODA), 4,4′-(4,4′-isopropyl biphenoxy)biphthalic anhydride (BPADA), 2,2′-bis-(3,4-dicarboxylic phenyl)hexafluoropropane dianhydride (6FDA), and ethylene glycol bis(anhydride-trimellitate) (TMEG) may be used.

As the diamine suitable in the present invention, at least one selected from the group consisting of p-phenylene diamine (PDA), m-phenylene diamine (m-PDA), 4,4′-oxydianiline (4,4′-ODA), 3,4′-oxydianiline (3,4′-ODA), 2,2-bis(4-[4-aminophenoxy]-phenyl)propane (BAPP), 1,3-bi(4-aminophenoxybenzene (TPE-R), 4,4′-bis(4-aminophenoxy)biphenyl (BAPB), 2,2-bis(4-[3-aminophenoxy]phenyl)sulfone (m-BAPS), 3,3′-dihydroxy-4,4′-diaminobiphenyl (HAB), and 4,4′-diaminobenzanilide (DABA) may be used.

In the present invention, a small amount of other dianhydride or diamine, or other compound, other than the above compounds, may be added, as necessary.

In the present invention, the organic solvent suitable to prepare the polyimide precursor solution may be selected from the group consisting of N-methyl pyrrolidinone (NMP), N,N-dimethyl acetamide (DMAc), tetrahydrofuran (THF), N,N-dimethyl formamide (DMF), dimethyl sulfoxide (DMSO), cyclohexane, acetonitrile, and a mixture thereof, but is not limited thereto.

The polyimide precursor is preferably present in the entire solution at a 5 to 30 wt %. If the content thereof is below 5 wt %, unnecessary solvent may be more used, and if the content thereof is above 30 wt %, viscosity of the solution may be excessively high, and thus uniform coating may not be realized.

In addition, in order to facilitate coating or curing or improve other physical properties, additives such as an antifoaming agent, a gel agent, a hardening accelerator, and the like, may be further added.

Hereinafter, a manufacturing method of the multilayer polyimide flexible metal-clad laminate of the present invention will be described.

The present invention provides a manufacturing method of the multilayer polyimide flexible metal-clad laminate, the method including: structuring two or more polyimide precursor layers, having different coefficients of linear thermal expansion after curing, on one surface or two surfaces of a metal foil, continuously without drying, followed by drying and curing, to thereby form multiple layers of polyimide and gradient layers each between polyimide layers of the multiple layers of polyimide, the gradient layer having a gradual change in coefficient of linear thermal expansion between the polyimide layers.

In the manufacturing method of the multilayer polyimide flexible metal-clad laminate according to the present invention, the polyimide layers each have a coefficient of linear thermal expansion of 10˜100 ppm/K. If the coefficient of linear thermal expansion thereof is below 10 ppm/K or above 100 ppm/K, the adhesion between the metal foil and the polyimide layer may be deteriorated or a delamination phenomenon may occur at an interface between the metal foil and the polyimide layer at the time of drying and curing processes, due to the difference in coefficient of linear thermal expansion between the metal foil and the polyimide layer.

In addition, the present invention is characterized in that the difference in coefficient of linear thermal expansion between the polyimide layers is 10˜90 ppm/K.

In the present invention, the polyimide layers each preferably have a thickness of 1˜30 μm. If the thickness thereof is below 1 μm, coating may be difficult through a general coating method, and if the thickness thereof is above 30 μm, a curling of the film due to evaporation of solvent may be severe at the time of drying and curing processes.

The metal foil according to the present invention may be formed of one or two or more selected from copper, aluminum, iron, silver, palladium, nickel, chrome, molybdenum, tungsten, and an alloy thereof.

In the foregoing manufacturing method, different polyimide precursor layers may be continuously structured by applying a multi-coating method. The term “continuously structured” means “without involving a drying process between layers”. The structuring may be carried out by one or two or more selected from knife coating, roll coating, slot die coating, lip die coating, slide coating, and curtain coating.

Hereinafter, the term “structuring” herein will be described in detail with reference to the accompanying drawings.

FIG. 1 shows a cross-sectional view of, in a manufacturing method of a flexible metal-clad laminate composed of three polyimide layers, a laminate where a gradient layer (mixing layer) is formed between the respective polyimide layers by continuously multi-coat three different polyimide precursor layers without a drying process, followed by drying and imidization.

As the coating method applicable in the present invention, among knife coating, roll coating, slot die coating, lip die coating, slide coating, curtain coating, and the like, the same kind of coating method or different kinds of coating methods may be sequentially carried out two times or more, or structuring may be continuously conducted by using multi die coating, but is not particularly limited thereto.

The present invention will be described in detail by explaining more specific examples and comparative examples of the present invention below. However, the present invention is not limited to the examples and comparative examples below, and may be embodied into various types of examples within the scope of the appended claims. Rather, the embodiments below may be provided so that this disclosure will be thorough and complete, and the present invention can be easily practiced by those skilled in the art.

The abbreviations used in the examples are as follows.

DMAc: N-N-dimethylacetamide

BPDA: 3,3′,4,4′-biphenyltetracarboxylic acid dianhydride

PDA: p-phenylenediamine

ODA: 4,4′-diaminodiphenylether

BAPB: 4,4′-bis(4-aminophenoxy)biphenyl

Physical properties stated in the present invention were measured by the following methods.

1. Coefficient of Linear Thermal Expansion (CTE)

Coefficient of linear thermal expansion was obtained by measuring thermal expansion values using a thermomechanical analyzer (TMA) while the temperature was raised to 400° C. at a rate of 5° C./min and averaging thermal expansion values between 100° C. and 250° C. among the measured values.

2. Adhesion Between Polyimide Resin and Metal Foil

In order to determine adhesion (peel strength) between a polyimide resin and a metal foil, a metal layer of a laminate was patterned to have a width of 1 mm, and then the 180° peel strength thereof was measured using a universal testing machine (UTM).

3. Dimensional Change After Etching

It was determined according to the ‘Method B’ of IPC-TM-650, 2.2.4. After position recognizing holes were drilled in four vertexes of a square sample of 275×255 mm in MD and TD, the sample was stored in a thermohygrostat of 23° C. and 50% RH for 24 hours. Then, respective distances between holes were repetitively measured three times and then averaged. After that, a metal foil was etched, and then stored in a thermohygrostat of 23° C. and 50% RH for 24 hours. Then, the distances between holes were again measured. The changes in MD and TD of the thus measured values were calculated.

4. Observation of Bubble Formation

The number of bubble generated in a surface area of 50 cm×50 cm was measured five times, and then average thereof was recorded. “No” was recorded when no foam was present, and “Interfacial delamination” was recorded when the bubble was all over the surface.

### SYNTHETIC EXAMPLE 1

Diamines of PDA 12.312 g and ODA 2.533 g were completely dissolved in 211.378 g of a DMAc solution by stirring, under the nitrogen atmosphere, and then BPDA 38.000 g as dianhydride was added thereto in several lots. Thereafter, stirring was subsequently performed for about 24 hours, thereby preparing a polyamic acid solution. The polyamic acid solution thus prepared was cast on a 20 μm-thick film, and then curing was performed by raising the temperature to 350° C. for 60 minutes and maintaining the temperature for 30 minutes. The measured coefficient of linear thermal expansion was 13.4 ppm/K.

### SYNTHETIC EXAMPLE 2

Diamines of PDA 3.278 g and ODA 2.024 g were completely dissolved in 117.072 g of a DMAc solution by stirring, under the nitrogen atmosphere, and then BPDA 12.000 g as dianhydride was added thereto in several lots. Thereafter, stirring was subsequently performed for about 24 hours, thereby preparing a polyamic acid solution. The polyamic acid solution thus prepared was cast on a 20 μm-thick film, and then curing was performed by raising the temperature to 350° C. for 60 minutes and maintaining the temperature for 30 minutes. The measured coefficient of linear thermal expansion was 19.5 ppm/K.

### SYNTHETIC EXAMPLE 3

Diamines of PDA 2.186 g and ODA 4.047 g were completely dissolved in 117.072 g of a DMAc solution by stirring, under the nitrogen atmosphere, and then BPDA 12.000 g as dianhydride was added thereto in several lots. Thereafter, stirring was subsequently performed for about 24 hours, thereby preparing a polyamic acid solution. The polyamic acid solution thus prepared was cast on a 20 μm-thick film, and then curing was performed by raising the temperature to 350° C. for 60 minutes and maintaining the temperature for 30 minutes. The measured coefficient of linear thermal expansion was 34.0 ppm/K.

### SYNTHETIC EXAMPLE 4

Diamine of BAPB 948 g was completely dissolved in 11.572 g of a DMAc solution by stirring, under the nitrogen atmosphere, and then BPDA 757 g as dianhydride was added thereto. Thereafter, stirring was subsequently performed for about 24 hours, thereby preparing a polyamic acid solution. The polyamic acid solution thus prepared was cast on a 20 μm-thick film, and then curing was performed by raising the temperature to 350° C. for 60 minutes and maintaining the temperature for 30 minutes. The measured coefficient of linear thermal expansion was 65.1 ppm/K.

### EXAMPLE 1

The polyamic acid solution prepared through [Synthetic Example 1] was coated on a 12 μm-thick rolled and annealed copper foil (Rz=1.0 μm) by using a lip die such that the thickness thereof after curing became 3 μm. Then, the polyamic acid solution prepared through [Synthetic Example 4] directly above and the polyamic acid solution prepared through [Synthetic Example 1] were continuously coated thereon by using a multi slot die such that the thicknesses thereof after curing became 20 μm and 3 μm, respectively. These coatings were allowed to stay in a dryer at 130° C. for 15 minutes, and then stay in a roll to roll curing machine while the temperature was raised from 150° C. to 390° C. for 10 minutes and maintained at 390° C. for 5 minutes, for a curing process. The results were tabulated in Table 1.

### EXAMPLE 2

The polyamic acid solution prepared through [Synthetic Example 1] was coated on a 12 μm-thick rolled and annealed copper foil (Rz=1.0 μm) by using a lip die such that the thickness thereof after curing became 3 μm. Then, the polyamic acid solution prepared through [Synthetic Example 4] directly above and the polyamic acid solution prepared through [Synthetic Example 1] were continuously coated thereon by using a multi slot die such that the thicknesses thereof after curing became 20 μm and 3 μm, respectively. These coatings were allowed to stay in a dryer at 130° C. for 15 minutes, and then stay in a roll to roll curing machine while the temperature was raised from 150° C. to 390° C. for 5 minutes and maintained at 390° C. for 5 minutes, for a curing process hardening procedure. The results were tabulated in Table 1.

### COMPARATIVE EXAMPLE 1

The polyamic acid solution prepared through [Synthetic Example 1] was coated on a 12 μm-thick rolled and annealed copper foil (Rz=1.0 μm) by using a lip die such that the thickness thereof after curing became 3 μm, and dried in a drier at 130° C. for 5 minutes, to form a first polyimide precursor layer. Then, the polyamic acid solution prepared through [Synthetic Example 4] was coated thereon under the same conditions such that the thicknesses thereof after curing became 20 μm, and then dried, to thereby form a second polyimide precursor layer. Then, the polyamic acid solution prepared through [Synthetic Example 1] was again coated thereon under the same conditions such that the thicknesses thereof after curing became 3 μm, and then dried, to thereby form a third polyimide precursor layer. These polyimide precursor layers were allowed to stay in a roll to roll hardener while the temperature was raised from 150° C. to 390° C. for 10 minutes and maintained at 390° C. for 5 minutes, for a curing process. The results were tabulated in Table 1.

### COMPARATIVE EXAMPLE 2

The polyamic acid solution prepared through [Synthetic Example 1] was coated on a 12 μm-thick rolled and annealed copper foil (Rz=1.0 μm) by using a lip die such that the thickness thereof after curing became 3 μm, and dried in a drier at 130° C. for 5 minutes, to form a first polyimide precursor layer. Then, the polyamic acid solution prepared through [Synthetic Example 4] was coated thereon under the same conditions such that the thicknesses thereof after curing became 20 μm, and then dried, to thereby form a second polyimide precursor layer. Then, the polyamic acid solution prepared through [Synthetic Example 1] was again coated thereon under the same conditions such that the thicknesses thereof after curing became 3 μm, and then dried, to thereby form a third polyimide precursor layer. These polyimide precursor layers were allowed to stay in a roll to roll curing machine while the temperature was raised from 150° C. to 390° C. for 5 minutes and maintained at 390° C. for 5 minutes, for a curing process. The results were tabulated in Table 1.

### COMPARATIVE EXAMPLE 3

The polyamic acid solution prepared through [Synthetic Example 2] was coated on a 12 μm-thick rolled and annealed copper foil (Rz=1.0 μm) by using a lip die such that the thickness thereof after hardening became 3 μm, and dried in a drier at 130° C. for 5 minutes, to form a first polyimide precursor layer. Then, the polyamic acid solution prepared through [Synthetic Example 4] was coated thereon under the same conditions such that the thicknesses thereof after curing became 20 μm, and then dried, to thereby form a second polyimide precursor layer. Then, the polyamic acid solution prepared through [Synthetic Example 2] was again coated thereon under the same conditions such that the thicknesses thereof after curing became 3 μm, and then dried, to thereby form a third polyimide precursor layer. These polyimide precursor layers were allowed to stay in a roll to roll curing machine while the temperature was raised from 150° C. to 390° C. for 10 minutes and maintained at 390° C. for 5 minutes, for a curing process. The results were tabulated in Table 1.

### COMPARATIVE EXAMPLE 4

The polyamic acid solution prepared through [Synthetic Example 3] was coated on a 12 μm-thick rolled and annealed copper foil (Rz=1.0 μm) by using a lip die such that the thickness thereof after curing became 3 μm, and dried in a drier at 130° C. for 5 minutes, to form a first polyimide precursor layer. Then, the polyamic acid solution prepared through [Synthetic Example 4] was coated thereon under the same conditions such that the thicknesses thereof after curing became 20 μm, and then dried, to thereby form a second polyimide precursor layer. Then, the polyamic acid solution prepared through [Synthetic Example 3] was again coated thereon under the same conditions such that the thicknesses thereof after curing became 3 μm, and then dried, to thereby form a third polyimide precursor layer. These polyimide precursor layers were allowed to stay in a roll to roll curing machine while the temperature was raised from 150° C. to 390° C. for 10 minutes and maintained at 390° C. for 5 minutes, for a curing process. The results were tabulated in Table 1.

TABLE 1

| | Adhesion | Dimensional | Number of |
|---|---|---|---|
| | (kgf/cm) | Change (MD/TD, %) | Foam |
| Example 1 | 1.0 | −0.019/−0.030 | 0 |
| Example 2 | 0.9 | −0.031/−0.038 | 0.2 |
| Comparative | 1.0 | Hardly | 1.9 |
| Example 1 | | Measurable | |
| Comparative | Not | Not | Interfacial |
| Example 2 | Measurable | Measurable | Delamination |
| Comparative | 0.7 | 0.005/−0.014 | 0 |
| Example 3 | | | |
| Comparative | 1.1 | −0.079/−0.093 | 0 |
| Example 4 | | | |

As seen from the above table, it was confirmed that the multilayer polyimide flexible metal-clad laminate according to the present invention had excellent adhesion, a small dimensional change, and good external appearance after hardening.

As set forth above, in the multilayer polyimide flexible metal-clad laminate where two or more polyimide layers are laminated on one surface or two surfaces of a metal foil, the polyimide precursor layers for polyimide layers having different coefficients of linear thermal expansion are continuously structured by a multi-coating method, followed by drying and imidization, so that there can be provided a flexible metal-clad laminate for a printed circuit board capable of solving a delamination problem between the polyimide layers and having excellent dimensional stability, and a manufacturing method thereof.

What is claimed is:

1. A multilayer polyimide flexible metal-clad laminate where multiple layers of polyimide are structured on one surface or two surfaces of a metal foil, the multilayer polyimide flexible metal-clad laminate comprising:
multiple layers of polyimide having different coefficients of linear thermal expansion; and
gradient layers each formed between polyimide layers of the multiple layers of polyimide, the gradient layer having a gradual change in coefficient of linear thermal expansion between the polyimide layers.

2. The multilayer polyimide flexible metal-clad laminate of claim 1, wherein the multiple layers of polyimide include an n-th (n≧1) polyimide layer and an n+1-th (n≧1) polyimide layer; and wherein the gradient layers include a gradient layer of the n-th polyimide layer and the n+1-th polyimide layer, the gradient layer having a gradual change in coefficient of linear thermal expansion between the n-th polyimide layer and the n+1-th polyimide layer.

3. The multilayer polyimide flexible metal-clad laminate of claim 1, wherein the polyimide layers each have a coefficient of linear thermal expansion of 10˜100 ppm/K.

4. The multilayer polyimide flexible metal-clad laminate of claim 3, wherein the difference of coefficient of linear thermal expansion between the polyimide layers is 10˜90 ppm/K.

5. The multilayer polyimide flexible metal-clad laminate of claim 1, wherein the polyimide layers each have a thickness of 1˜30 μm.

6. The multilayer polyimide flexible metal-clad laminate of claim 1, wherein the metal foil formed of any one selected from copper, aluminum, iron, silver, palladium, nickel, chrome, molybdenum, tungsten, and an alloy thereof.

7. A manufacturing method of a multilayer polyimide flexible metal-clad laminate on one surface or two surfaces of a metal foil, the method comprising:
structuring two or more polyimide precursor layers continuously without drying, followed by drying and hardening at a time, to thereby form multiple layers of polyimide and gradient layers each between polyimide layers of the multiple layers of polyimide, the gradient layer having a gradual change in coefficient of linear thermal expansion between the polyimide layers.

8. The method of claim 7, wherein the polyimide layers each have a coefficient of linear thermal expansion of 10˜100 ppm/K.

9. The method of claim 8, wherein the difference of coefficient of linear thermal expansion between the polyimide layers is 10˜90 ppm/K.

10. The method of claim 7, wherein the polyimide layers each have a thickness of 1˜30 μm.

11. The method of claim 7, wherein the metal foil is formed of any one selected from copper, aluminum, iron, silver, palladium, nickel, chrome, molybdenum, tungsten, and an alloy thereof.

12. The method of claim 7, wherein the structuring is carried out by one or two or more selected from knife coating, roll coating, slot die coating, lip die coating, slide coating, and curtain coating.
